(19) United States
(12) Patent Application Publication
(10) Pub. No.: US 2009/0283887 A1
(43) Pub. Date: Nov. 19, 2009

(54) OPTICAL SEMICONDUCTOR DEVICE

(75) Inventor: Yoshiki Takayama, Shiga (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/428,513

(22) Filed: Apr. 23, 2009

(30) Foreign Application Priority Data
May 16, 2008 (JP) 2008-128964

(51) Int. Cl. H01L 23/00

(52) U.S. Cl. 257/680; 257/E23.002

(57) ABSTRACT

An optical semiconductor device of the present invention includes a semiconductor chip (11) having an optical element (12) formed on a surface of the semiconductor chip; and a transparent member (13) directly secured on the semiconductor chip (11) with a transparent adhesive (25) so as to cover the optical element (12). The transparent member (13) has a surface opposed to the semiconductor chip (11) and at least one edge line of the surface has one of a chamfered portion (14) and a rounded portion.

### FIELD OF THE INVENTION

The present invention relates to an optical semiconductor device and particularly relates to an optical semiconductor device having a transparent member directly secured on a semiconductor chip having an optical element.

### BACKGROUND OF THE INVENTION

In recent years, electronic equipment has increasingly been reduced in size and there has been a growing need for smaller optical semiconductor devices used for electronic equipment. In optical semiconductor devices of the prior art, semiconductor chips having optical elements formed thereon are stored in recessed bases and the openings of the bases are sealed with transparent members such as protective glass. In order to reduce the sizes of the optical semiconductor devices, the outside shapes of the bases are reduced by shortening the bonding widths of the transparent members on the side walls of the bases and reducing the widths of the side walls.

In an optical semiconductor device further reduced in size and thickness from these optical semiconductor devices, a transparent member directly secured on a semiconductor chip is stored in a recessed base and molding resin is injected into the base (for example, see Japanese Patent Laid-Open No. 2007-142194).

In order to reduce the size of the optical semiconductor device, it is necessary to reduce the size of the transparent member without causing any problems in optical characteristics. This is because the dimensions of the transparent member affect the dimensions of the semiconductor chip. For example, on the semiconductor chip, it is necessary to obtain a certain distance between the electrode pads of the semiconductor chip and the transparent member so as not to allow the interference of capillaries for wire bonding the electrode pads. Further, in order to prevent an adhesive for securing the transparent member to the semiconductor chip from being spread over the electrode pads and the outer periphery of the semiconductor chip, it is necessary to obtain a certain distance between the transparent member and the electrode pads.

The dimensions of the transparent member have to be reduced in consideration of tolerances such as a dimensional tolerance and a bonding position tolerance without causing any optical problems such as vignetting even on incident light having the maximum angle of incidence. For this purpose, the transparent member has to be shaped so as to obtain a wide area allowing light incident on the transparent member to normally travel. Under the present circumstances, a typically flat transparent member is used which has the sides perpendicular to the top and bottom surfaces of the transparent member.

The transparent member is stored in a transport tray before being used. Thus the edge lines of the undersurface of the transparent member and the inner sides (tilted) of a recessed storage part of the tray may interfere with each other and cause falling chippings from the transparent member and shavings from the tray. Such chippings and shavings are likely to adhere to the transparent member and may interfere with incident light, so that optical failures may occur.

### DISCLOSURE OF THE INVENTION

The present invention has been devised in view of the problem. An object of the present invention is to provide an optical semiconductor device which can prevent the formation of a deposit on a transparent member while reducing the size of the transparent member directly secured on a semiconductor chip, thereby preventing failures in optical characteristics.

In order to attain the object, the edge lines of a transparent member opposed to a semiconductor chip are chamfered or rounded in the present invention. To be specific, an optical semiconductor device of the present invention includes: a semiconductor chip having an optical element formed on a surface of the semiconductor chip; and a transparent member directly secured on the semiconductor chip with a transparent adhesive so as to cover the optical element, wherein the transparent member has a surface opposed to the semiconductor chip and at least one edge line of the surface has one of a chamfered portion and a rounded portion.

With this configuration, even when the transparent member is stored in a transport tray, chippings hardly fall from the transparent member and shavings hardly occur on the transport tray. Thus it is possible to prevent the formation of a deposit on the transparent member to prevent failures in the optical characteristics.

It is preferable that one of the chamfered portion and the rounded portion of the transparent member is formed in a range not allowing incident light with the maximum angle of incidence relative to the transparent member to be incident on the optical element after reaching one of the chamfered portion and the rounded portion.

Further, it is preferable that the transparent adhesive is also injected between one of the chamfered portion and the rounded portion of the transparent member and the semiconductor chip.

It is preferable that the transparent member and the transparent adhesive have the same index of refraction. Thus no optical loss occurs on the interface between the transparent member and the transparent adhesive and light incident on the transparent member can be normally incident on the optical element. This means that even the transparent member having one of the chamfered portion and the rounded portion can be reduced in size as in a flat transparent member of the prior art.

The semiconductor chip may have electrodes formed on the same plane as the optical element, a different surface from the optical element, or both surfaces of the optical element. Further, the optical semiconductor device may further include conductors penetrating the semiconductor chip; and electrodes formed on both ends of the conductors.

The optical semiconductor device may further include a base having a mounting portion to which the semiconductor chip is secured and conductors to which the electrodes of the semiconductor chip are directly connected or electrically connected via wires; and a resin portion for molding the outer periphery of the transparent member and the semiconductor chip except for a portion on the transparent member.

Moreover, the optical semiconductor device may further include substrates on the outer peripheral sides of the transparent member, the substrates being electrically connected directly to the electrodes of the semiconductor chip. The optical semiconductor device may further include wires formed on the transparent member, the wires being electrically connected directly to the electrodes of the semiconductor chip.

### BRIEF DESCRIPTION OF THE DRAWINGS

FIGS. 1A and 1B show the configuration of an optical semiconductor device according to an embodiment of the present invention;

FIGS. 2A, 2B, and 2C show a state in which a transparent member of the optical semiconductor device in FIG. 1 is stored in a transport tray, in comparison with a transparent member of the prior art;

FIGS. 3A, 3B, and 3C are enlarged views showing a part of the transparent member of the optical semiconductor device shown in FIG. 1;

FIGS. 4A and 4B show the configuration of an optical semiconductor device according to another embodiment of the present invention;

FIGS. 5A and 5B show the configuration of an optical semiconductor device according to still another embodiment of the present invention;

FIGS. 6A and 6B show the configuration of an optical semiconductor device according to still another embodiment of the present invention;

FIGS. 7A and 7B show the configuration of an optical semiconductor device according to still another embodiment of the present invention; and

FIGS. 8A and 8B show the configuration of an optical semiconductor device according to still another embodiment of the present invention.

### DESCRIPTION OF THE EMBODIMENTS

The following will describe embodiments of the present invention with reference to the accompanying drawings.

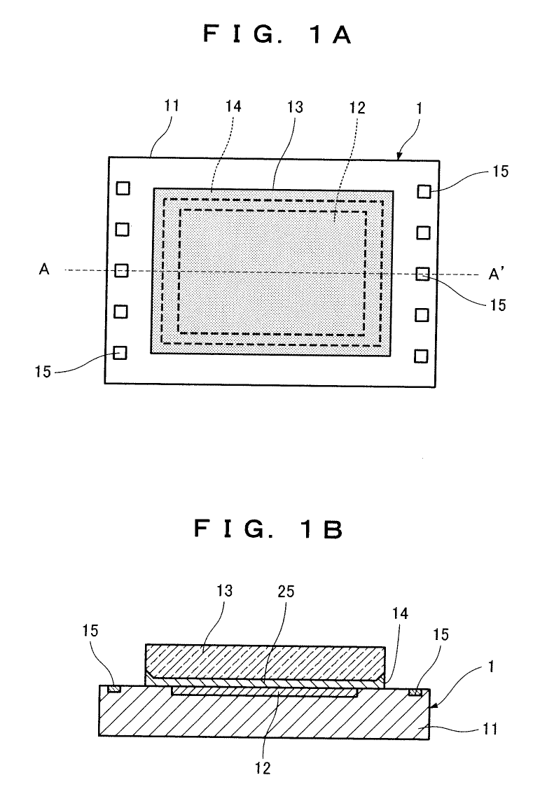

FIG. 1A is an A plan view showing an optical semiconductor device according to the embodiment of the present invention. FIG. 1B is a sectional view of the optical semiconductor device.

In FIGS. 1A and 1B, an optical semiconductor device 1 includes a semiconductor chip 11 having a surface on which an optical element 12 and electrode pads 15 are formed, and a transparent member 13 directly bonded on the semiconductor chip 11 with a transparent adhesive 25 so as to cover the optical element 12. The transparent member 13 is a plate made of a material such as glass and is shaped like a rectangle in planar view. On the undersurface (a surface opposed to the semiconductor chip 11) of the transparent member 13, all the edge lines are chamfered to form chamfered portions 14. The transparent adhesive 25 is also injected between the chamfered portions 14 and the top surface of the semiconductor chip 11. The transparent member 13 and the transparent adhesive 25 have the same index of refraction.

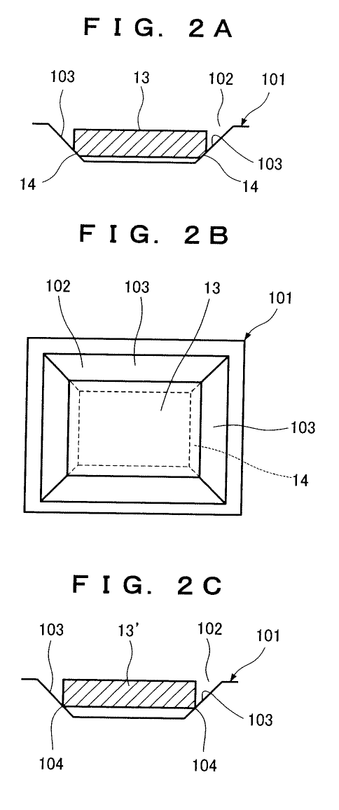

As shown in FIGS. 2A and 2B, the transparent member 13 is horizontally stored in a plurality of recessed storage parts 102 (only one of which is illustrated) of a transport tray 101 before the optical semiconductor device 1 is assembled. The transport tray 101 is a typical tray and is molded with resin in view of productivity, cost, and functionality. The storage part 102 is a recess shaped like a quadrangular pyramid with an expanding opening. Further, the angle of tilt of the chamfered portion 14 relative to the undersurface of the transparent member 13 is substantially equal to the angle of tilt of an inner surface 103 relative to the bottom of the storage part 102.

Thus the transparent member 13 is guided at the chamfered portions 14 by the inner surfaces 103 during storage and is placed into a predetermined position with a predetermined orientation in the storage part 102, and the state is kept during transportation. The chamfered portions 14 and the inner surfaces 103 face each other and do not interfere with each other, so that chippings hardly fall from the transparent member 13 and shavings hardly occur on the transport tray 101. Thus it is possible to prevent the formation of a deposit on the transparent member 13 to prevent failures in the optical characteristics of the optical semiconductor device 1. For comparison, FIG. 2C shows a transparent member 13′ of the prior art. Since edge lines 104 of the transparent member 13′ interfere with the inner surfaces 103, chippings fall from the transparent member 13′ and shavings occur on the transport tray 101.

The chamfered portions 14 are formed in ranges not interfering with light incident on the optical element 12 with the maximum angle of incidence relative to the transparent member 13. In other words, on the transparent member 13, the chamfered portions 14 are formed in ranges not allowing light incident with the maximum angle of incidence relative to the transparent member 13 to be incident on the optical element 12 after reaching the chamfered portions 14.

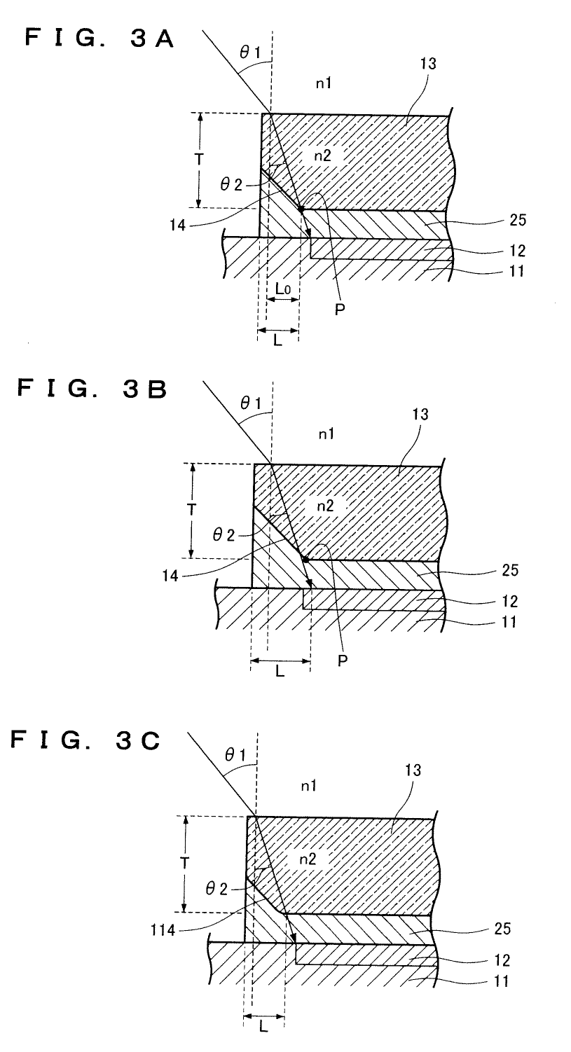

For example, as shown in FIG. 3A, light incident from air to the transparent member 13 has the maximum angle of incidence of 01 and an angle of refraction of θ2, air has an absolute refractive index of n1, and the transparent member has an absolute refractive index of n2 and a thickness of T. In this case, according to Snell's law (n1·-sinθ1=n2·sinθ2), a dimension L not interfering with light incident on the optical element 12 on the undersurface of the transparent member 13 has to be at least Tanθ2×T (designated as L0) from the edge line (designated as position P) of the transparent member 13. The chamfered portion 14 is worked such that a region having the dimension L is disposed on the outer periphery so as to be somewhat separated from the optical element 12.

However, as has been discussed about the optical semiconductor device 1 of FIG. 1, the transparent adhesive 25 is also injected between the chamfered portions 14 of the transparent member 13 and the top surface of the semiconductor chip 11. When the transparent member 13 and the transparent adhesive 25 are adjusted to the same index of refraction, no optical loss occurs on the interfaces between the chamfered portions 14 and the transparent member 13 and light reaching the chamfered portions 14 can be normally incident on the optical element 12.

This means that the region having the dimension L in FIG. 3B can be closer to the optical element 12 than in FIG. 3A. Thus when the transparent member 13 has the same dimension as the flat transparent member of the prior art (for example, a dimension indicated by a virtual line), the chamfered portions 14 can be worked while achieving size reduction. The same effect can be obtained by forming a rounded portion 114 as shown in FIG. 3C instead of the chamfered portion 14.

In the optical semiconductor device 1 of FIG. 1, the chamfered portions 14 are formed on all the edge lines (four sides) of the undersurface of the transparent member 13. The chamfered portions 14 may be formed only on the edge lines of the opposed two sides, one of the sides, or three of the sides according to the configuration of the optical semiconductor device 1.

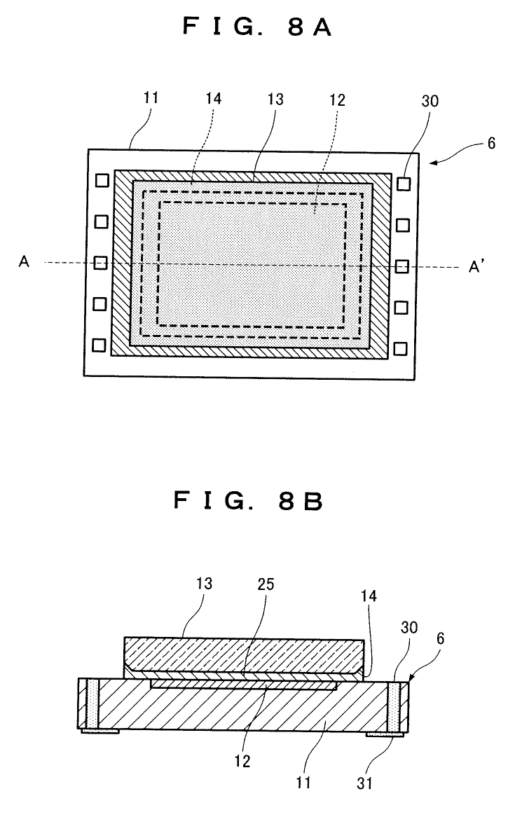

In the optical semiconductor device 1 of FIG. 1, the electrode pads 15 are arranged along a pair of opposite sides of the optical element 12 (and the semiconductor chip 11) on the same plane as the optical element 12. The present invention is not limited to this configuration. For example, the electrode pads 15 may be arranged along one of the sides or the four sides of the optical element 12. Alternatively, the electrode pads 15 may be formed on a different surface from the optical element 12 or on both surfaces of the optical element 12 (see FIG. 8).

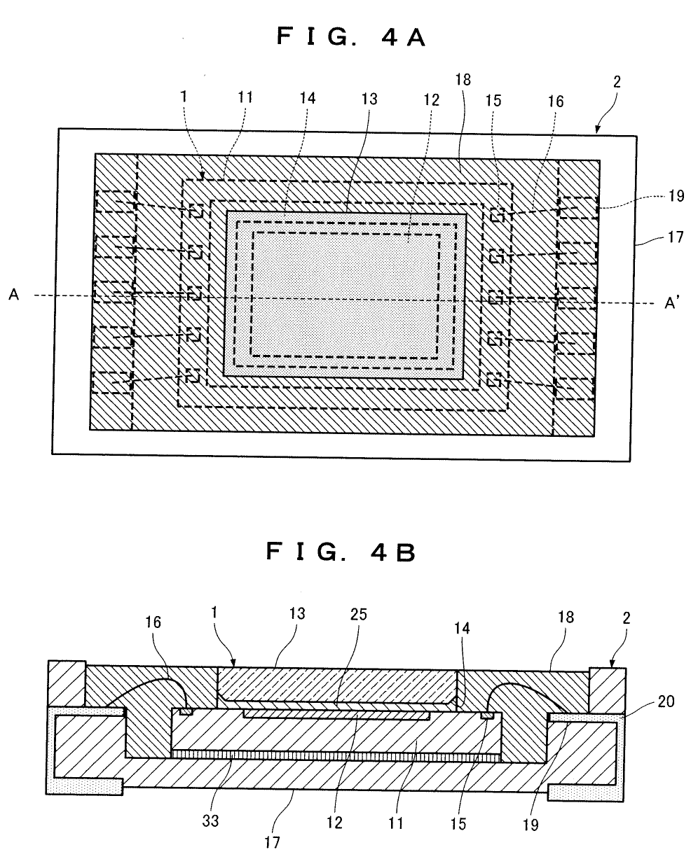

An optical semiconductor device 2 of FIGS. 4A and 4B is a package of the optical semiconductor device 1. The optical semiconductor device 1 is secured to a mounting portion in a recessed base 17 with a die bonding adhesive 33, the electrode pads 15 of the semiconductor chip 11 and internal terminals 19 of conductors 20 formed through the base 17 are connected to each other via wires 16, and molding resin 18 is injected into the base 17 except for a portion on the transparent member 13. The other configurations are similar to the configurations of the optical semiconductor device 1. The molding resin 18 may be injected over a recess in the base 17 or only into a part of the recess. When the molding resin 18 is a light shielding resin, the optical characteristics are further stabilized.

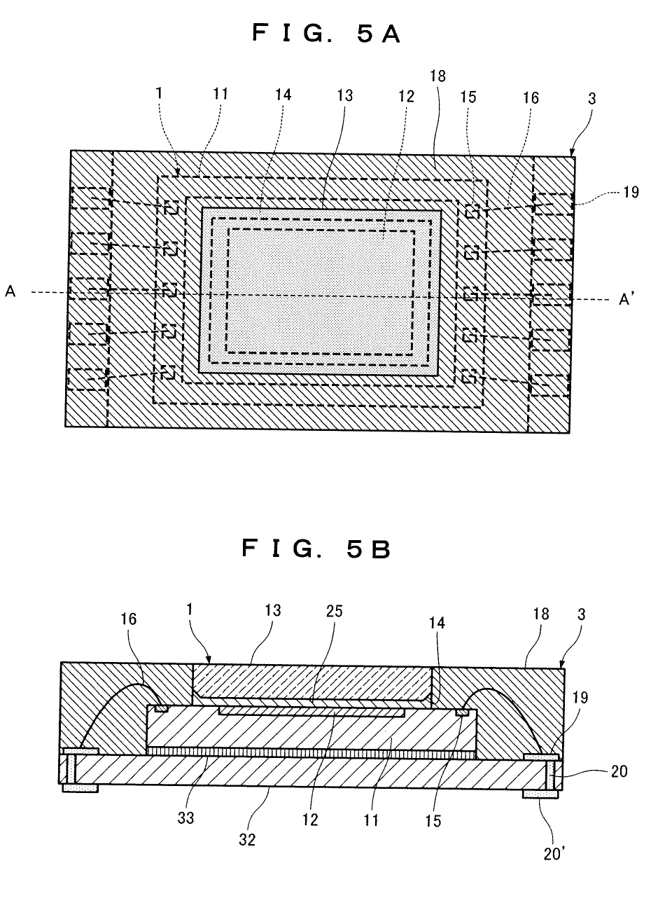

An optical semiconductor device 3 of FIGS. 5A and 5B is another package of the optical semiconductor device 1. The optical semiconductor device 1 is secured to a mounting portion of a flat base (for example, a substrate) 32 with a die bonding adhesive 33, the electrode pads 15 of the semiconductor chip 11 and internal terminals 19 on one end of conductors (vias) 20 formed through the base 32 are connected to each other via wires 16, and one surface of the base 32 is covered with molding resin 18 except for a portion on the transparent member 13. Reference numeral 20′ denotes external terminals. The other configurations are similar to the configurations of the optical semiconductor device 1. A lead frame may be used instead of the base 32, so that a configuration close to a general semiconductor package can be obtained and the cost can be reduced.

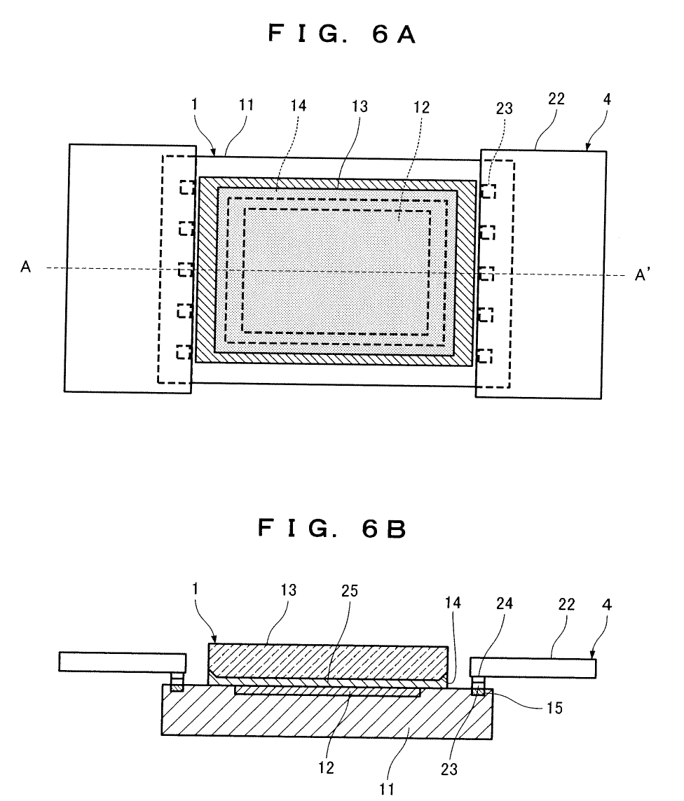

In an optical semiconductor device 4 of FIGS. 6A and 6B, the optical semiconductor device 1 is joined to substrates 22. Protruding electrodes 23 are formed on the electrode pads 15 of the semiconductor chip 11 of the optical semiconductor device 1, and the protruding electrodes 23 are directly connected to electrodes 24 of the substrates 22 disposed on outer peripheral sides of the transparent member 13. The other configurations are similar to the configurations of the optical semiconductor device 1. The optical semiconductor device 4 makes it possible to reduce the size and thickness of an optical module.

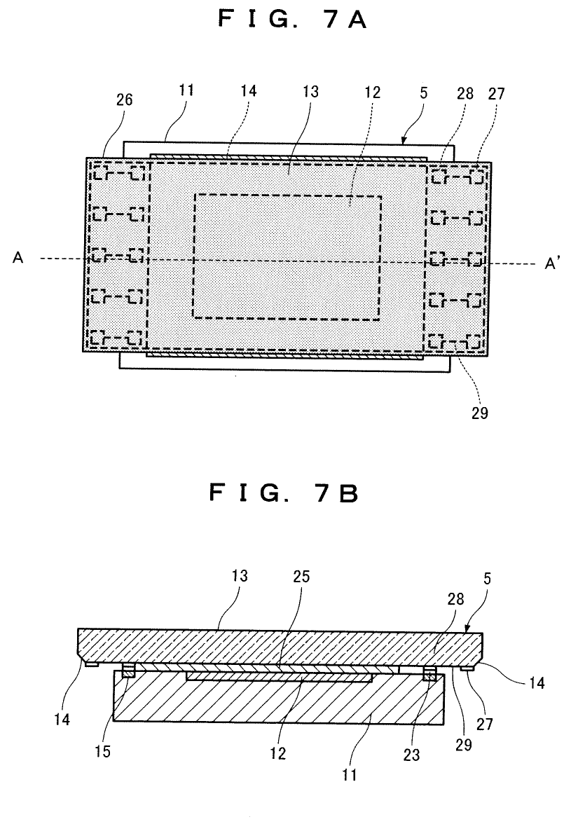

An optical semiconductor device 5 of FIGS. 7A and 7B is a modification of the optical semiconductor device 1. Protruding electrodes 23 are formed on the electrode pads 15 of the semiconductor chip 11. On the transparent member 13, electrodes 27 for connection to a mounting substrate, electrodes 28 opposed to the electrode pads 15, and wires 29 for electrically connecting the electrodes 27 and the electrodes 28 are formed. The electrode pads 15 and the electrodes 28 are connected to each other via the protruding electrodes 23. The other configurations are similar to the configurations of the optical semiconductor device 1. The optical semiconductor device 5 makes it possible to reduce the size and thickness of an optical module.

An optical semiconductor device 6 of FIGS. 8A and 8B is a modification of the optical semiconductor device 1. Vias 30 are formed on the semiconductor chip 11, and external connecting electrodes 31 connected to the vias 30 are formed on the other surface of the semiconductor chip 11. The other configurations are similar to the configurations of the optical semiconductor device 1. The optical semiconductor device 6 makes it possible to reduce the size and thickness of an optical module.

As has been discussed, according to the optical semiconductor device of the present invention, the edge lines of the transparent member are chamfered or rounded on the side of the semiconductor chip. Thus it is possible to prevent the formation of a deposit on the transparent member to prevent failures in the optical characteristics. By disposing the transparent adhesive also between the chamfered portions or the rounded portions and the semiconductor chip, it is possible to eliminate the need for an increased dimension of the transparent member as compared with the prior art. In other words, the optical semiconductor device of the present invention can prevent the formation of a deposit on the transparent member and stabilize the optical characteristics while achieving size reduction of the device. Thus the optical semiconductor device of the present invention is effective in reducing the size of electronic equipment in which the optical semiconductor device is mounted.

What is claimed is:

1. An optical semiconductor device, comprising:
a semiconductor chip having an optical element formed on a surface of the semiconductor chip; and
a transparent member directly secured on the semiconductor chip with a transparent adhesive so as to cover the optical element,
wherein the transparent member has a surface opposed to the semiconductor chip and at least one edge line of the surface has one of a chamfered portion and a rounded portion.

2. The optical semiconductor device according to claim 1, wherein one of the chamfered portion and the rounded portion of the transparent member is formed in a range not allowing incident light with a maximum angle of incidence relative to the transparent member to be incident on the optical element after reaching one of the chamfered portion and the rounded portion.

3. The optical semiconductor device according to claim 1, wherein the transparent adhesive is also injected between one of the chamfered portion and the rounded portion of the transparent member and the semiconductor chip.

4. The optical semiconductor device according to claim 1, wherein the transparent member and the transparent adhesive have a same index of refraction.

5. The optical semiconductor device according to claim 1, wherein the semiconductor chip has electrodes formed on a same plane as the optical element, a different surface from the optical element, or both surfaces of the optical element.

6. The optical semiconductor device according to claim 3, further comprising conductors penetrating the semiconductor chip; and
electrodes formed on both sides of the conductors.

7. The optical semiconductor device according to claim 1, further comprising a base having a mounting portion to which the semiconductor chip is secured and conductors to which electrodes of the semiconductor chip are directly connected or electrically connected via wires; and
a resin portion for molding an outer periphery of the transparent member and the semiconductor chip except for a portion on the transparent member.

8. The optical semiconductor device according to claim 1, further comprising substrates on outer peripheral sides of the transparent member, the substrates being electrically connected directly to electrodes of the semiconductor chip.

9. The optical semiconductor device according to claim 1, further comprising wires formed on the transparent member, the wires being electrically connected directly to electrodes of the semiconductor chip.
